(19) United States
(12) Patent Application Publication
(10) Pub. No.: US 2010/0290182 A1
(43) Pub. Date: Nov. 18, 2010

(54) POWER SUPPLY FAN

(75) Inventors: Guenter Baitz, Berlin (DE); Uwe Kirschke, Berlin (DE); Matthias Lenz, Schoenfliess (DE)

Correspondence Address: HARNESS, DICKEY & PIERCE, P.L.C., P.O. BOX 828, BLOOMFIELD HILLS, MI, 48303, US

(73) Assignee: WINCOR NIXDORF INTERNATIONAL GMBH, Paderborn (DE)

(21) Appl. No.: 12/812,128

(22) PCT Filed: Jan. 8, 2009
(86) PCT No.: PCT/EP09/00046

§ 371 Date: Jul. 8, 2010

(30) Foreign Application Priority Data
Jan. 23, 2008 (DE) 10 2008 005 723.1

(51) Int. Cl. G06F 1/20; H05K 7/20

(52) U.S. Cl. 361/679.48; 361/695

(57) ABSTRACT

A power supply fan, especially for a computer, comprises a fan case for a fan blower, the power supply fan being mounted on a power supply case surrounding a power supply unit and the fan case being at least partially arranged on the power supply case. The power supply fan is dimensioned in such a manner that it extends over at least one edge of a surface on which the power supply fan is fastened in such a manner that the interior of the power supply case and any electronic components adjacent to the power supply unit are supplied with an air stream.

### CROSS-REFERENCE TO RELATED APPLICATIONS

This application is a National Stage of International Application No. PCT/EP2009/000046, filed Jan. 8, 2009. This application claims the benefit and priority of German application 10 2008 005 723.1, filed Jan. 23, 2008. The entire disclosures of the above applications are incorporated herein by reference.

### BACKGROUND

This section provides background information related to the present disclosure which is not necessarily prior art.

1. Technical Field

The present invention relates to a power supply fan.

2. Discussion

Power supply fans are known intrinsically. They are usually designed in such a way that they are mounted either inside or outside a power supply unit case and they cool said power supply unit case during operation by introducing an air stream.

A power supply unit providing a cooling effect for a computer is known from DE 20 2004 013 516 U1 in which a separate cooling fan blower is housed in the power supply unit that is arranged in such a manner that the airstream created by the cooling fan blower is not ducted into the interior of the power supply unit, or does not remain there, but serves solely to dissipate the heat in the computer. The disadvantage is that locating an additional power supply fan on or in the power supply unit requires additional space, and the procurement and installation of this power supply fan creates additional costs.

### SUMMARY OF THE INVENTION

An object of the present invention is, therefore, to provide a power supply fan that eliminates the aforementioned disadvantages.

By using a power supply fan according to the preferred embodiment of the invention, not only the power supply unit itself is cooled by the air stream but also electronic components adjacent to the power supply unit. Installation of a power supply fan of this type requires only a minimal increase in space requirements. In addition, the costs for the procurement and installation of an additional cooling unit to cool electronic components adjacent to the power supply unit can be saved.

Additional advantageous configurations are identified in the dependent claims.

The electronic components that are arranged below the power supply unit can be cooled in a simple manner by having the power supply fan project beyond the lower edge of the end face of the power supply unit.

By forming projecting tabs on the power supply unit case, the power supply fan can be attached in a simple fashion to the power supply unit case so that the air stream emanating from the power supply fan flows not only into the interior of the power supply unit but also into areas into which the projecting tabs on the power supply unit case extend.

### BRIEF DESCRIPTION OF THE DRAWINGS

Embodiments are described in what follows using the appended drawings.

The drawings described herein are for illustrative purposes only of selected embodiments and not all possible implementations, and are not intended to limit the scope of the present disclosure.

FIG. 1 shows a perspective view of a power supply unit arranged above a mother board with a power supply fan according to the invention,

FIG. 2 shows a front view of a power supply unit arranged above a mother board with a power supply fan according to the invention,

FIG. 3 shows a rear view of a power supply unit arranged above a mother board with a power supply fan according to the invention,

FIG. 4 shows a side view of a power supply unit arranged above a mother board with a power supply fan according to the invention, and

FIG. 5 shows a plan view of a power supply unit arranged above a mother board with a power supply fan according to the invention.

Corresponding reference numerals indicate corresponding parts throughout the several views of the drawings.

### DETAILED DESCRIPTION OF THE PREFERRED EMBODIMENTS

Example embodiments will now be described more fully with reference to the accompanying drawings.

In the following description, terms such as top, bottom, left, right, front, back, refer only to the representation and position of the power supply fan and other parts selected as an example in the respective figures. These terms are not to be understood as restrictive, meaning that in different operating positions or as the result of mirror-image layouts or similar these references can change.

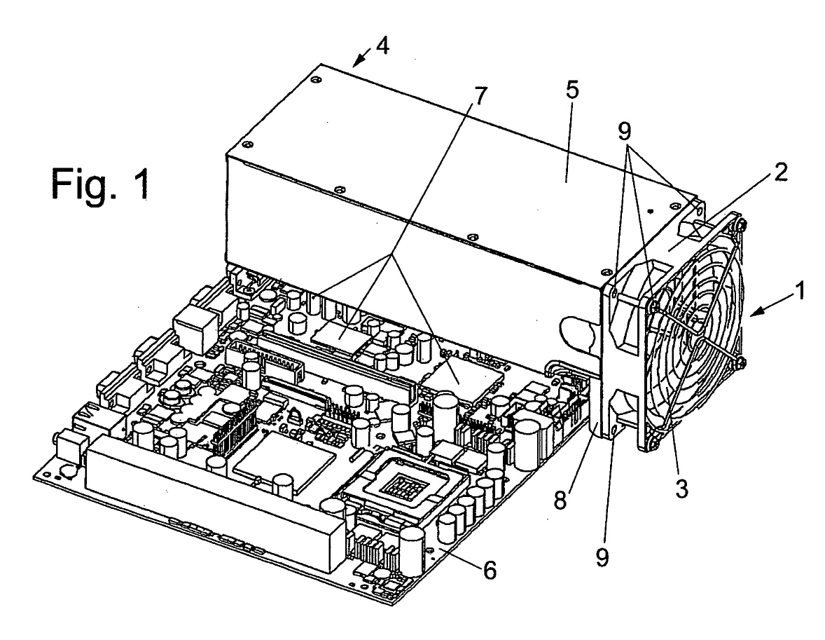

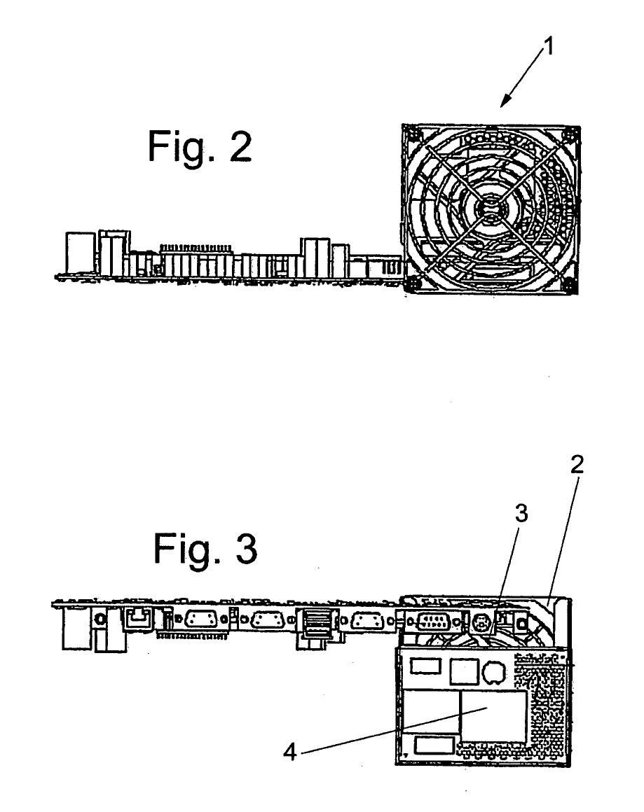

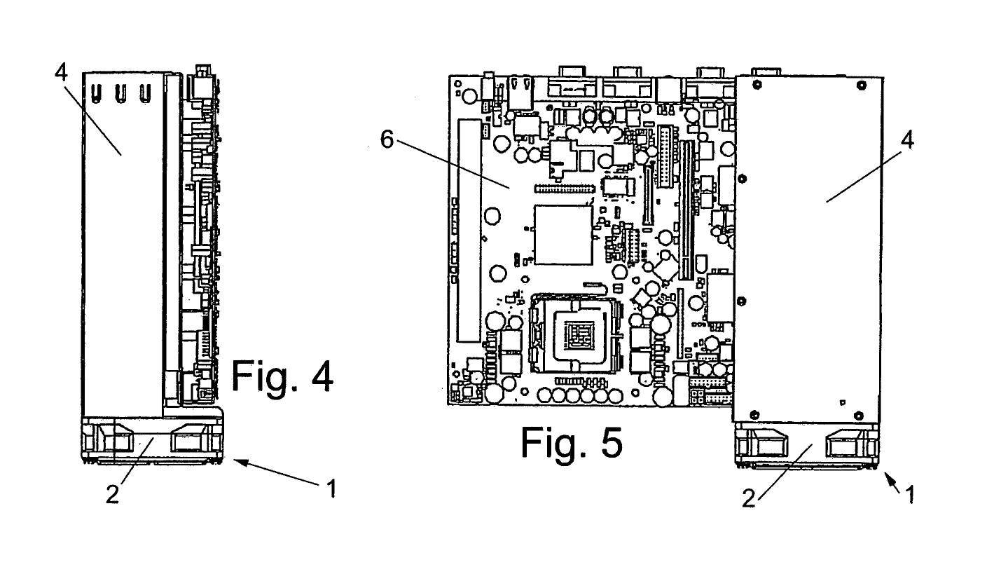

FIGS. 1 to 5 show the arrangement of the power supply fan on the power supply unit and the motherboard of the computer from different perspectives.

FIG. 1 shows a power supply unit 4 that is arranged above a motherboard 6. The power supply unit 4 is enclosed from all sides by a power supply unit case 5. A power supply fan 1 is mounted on the right end face of the power supply unit 4. The powers supply fan 1 is preferably attached to the power supply unit case 5 by being bolted to said case using bolts that are inserted through holes 9 in the corners of the fan case 2 and are screwed into matching threaded holes in the power supply case unit 5.

The power supply fan 1 is dimensioned such that it extends beyond at least one edge of the surface to which the power supply fan is attached. The result is that both the interior of the power supply unit case 5 as well as electronic components 7 adjacent to the power supply unit 4 are supplied with an air stream emanating from the power supply fan 1. The effective area of the power supply fan 1 preferably extends beyond one edge of the power supply unit facing the electronic components 7 lying under the power supply unit 4.

In a different embodiment (not shown), the power supply fan extends both beyond the lower edge of the end face of the power supply unit and beyond one of the lateral edges of the power supply unit so that the air stream emanating from the power supply fan reaches not only electronic components 7 lying under the power supply unit but also an area in the interior of the computer case lying next to the power supply unit at the level of the power supply unit body above the computer mother board.

To attach the power supply fan in a special embodiment, the power supply unit case 5 is configured in such a way that, on the end face to which the power supply fan 1 is attached, said case has at least one projecting tab 8 that extends beyond the end face of the power supply fan. In this way the power supply fan can be attached solely to the power supply unit case so configured. The power supply unit case preferably has two projecting tabs 8 on the end face of the power supply unit case 5 to which the power supply fan is attached.

Alternatively, the mother board 6 of the computer has fastening devices to attach the power supply fan so that the power supply fan is attached partially to the fastening device on the computer mother board 6 and partially to the power supply unit case 5.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

1. Power supply fan, particularly for computers, having a fan case for a fan blower, wherein the power supply fan is mounted externally to a power supply unit case enclosing a power supply unit and the fan case is arranged at least partially on the power supply unit case, characterized in that the power supply fan is dimensioned such that it extends at least beyond one edge of a surface to which the power supply fan is attached so that both the interior of the power supply unit case and electronic components adjacent to the power supply unit are supplied with an air stream.

2. Power supply fan from claim 1, wherein the power supply fan is dimensioned such that it extends beyond one edge of a surface on which the power supply fan is arranged, said edge facing electronic components lying below the power supply unit.

3. Power supply fan from claim 1, wherein the power supply fan extends beyond two edges of a surface on which the power supply fan is arranged, wherein the two edges of the surface touch at least one common edge point.

4. Power supply fan from claim 1, wherein the power supply unit case has at least one projecting tab on an end face on which the power supply fan is arranged, said edge extending beyond the end face of the power supply fan and the fan case is attached at least partially to this projecting tab.

5. Power supply fan from claim 1, wherein the fan case is arranged partially on the power supply unit case and partially on the mother board of the computer.

6. Power supply fan from claim 2, wherein the power supply fan extends beyond two edges of a surface on which the power supply fan is arranged, wherein the two edges of the surface touch at least one common edge point.

7. Power supply fan from claim 2, wherein the power supply unit case has at least one projecting tab on an end face on which the power supply fan is arranged, said edge extending beyond the end face of the power supply fan and the fan case is attached at least partially to this projecting tab.

8. Power supply fan from claim 3, wherein the power supply unit case has at least one projecting tab on an end face on which the power supply fan is arranged, said edge extending beyond the end face of the power supply fan and the fan case is attached at least partially to this projecting tab.

9. Power supply fan from claim 6, wherein the power supply unit case has at least one projecting tab on an end face on which the power supply fan is arranged, said edge extending beyond the end face of the power supply fan and the fan case is attached at least partially to this projecting tab.

10. Power supply fan from claim 2, wherein the fan case is arranged partially on the power supply unit case and partially on the mother board of the computer.

11. Power supply fan from claim 3, wherein the fan case is arranged partially on the power supply unit case and partially on the mother board of the computer.

12. Power supply fan from claim 4, wherein the fan case is arranged partially on the power supply unit case and partially on the mother board of the computer.

13. Power supply fan from claim 6, wherein the fan case is arranged partially on the power supply unit case and partially on the mother board of the computer.

14. Power supply fan from claim 7, wherein the fan case is arranged partially on the power supply unit case and partially on the mother board of the computer.

15. Power supply fan from claim 8, wherein the fan case is arranged partially on the power supply unit case and partially on the mother board of the computer.

16. Power supply fan from claim 9, wherein the fan case is arranged partially on the power supply unit case and partially on the mother board of the computer.
